(19) United States
(12) Patent Application Publication
(10) Pub. No.: US 2007/0257359 A1
(43) Pub. Date: Nov. 8, 2007

(54) Thermal Management Device For A Memory Module

(76) Inventors: Bradley E. Reis, Westlake, OH (US); Robert A. Reynolds III, Bay Village, OH (US); Martin David Smale, Parma, OH (US); Gregory Kramer, Lyndhurst, OH (US); Joseph Paul Capp, Strongsville, OH (US)

Correspondence Address: WADDEY & PATTERSON, P.C., 1600 DIVISION STREET, SUITE 500, NASHVILLE, TN, 37203, US

(21) Appl. No.: 11/742,812

(22) Filed: May 1, 2007

Related U.S. Application Data
(60) Provisional application No. 60/797,098, filed on May 3, 2006.

(51) Int. Cl. H01L 23/34

(52) U.S. Cl. 257/723

(57) ABSTRACT

A memory module which includes a memory board having two major surfaces, one of the major surfaces with a plurality of chips thereon, wherein at least one of the chips operates at a higher power than at least one other of the chips; and a thermal management system in thermal contact with one or more of the chips which operate at a higher power than at least one other of the chips, wherein the thermal management system spreads heat generated by the one or more of the chips which operate at a higher power than at least one other of the chips with which the thermal management system is in contact.

### RELATED APPLICATION

This application claims priority under 35 U.S.C. §119 from Provisional U.S. Patent Application having Ser. No. 60/797,098, entitled “Thermal Management Device For A Memory Module,” filed May 3, 2006, the disclosure of which is incorporated herein by reference.

### TECHNICAL FIELD

The present invention relates to a device or apparatus for thermal management for a memory module, as well as a memory module exhibiting improved thermal properties. More particularly, the inventive device functions to reduce hot spot temperatures resulting from various operating parameters of the memory modules

### BACKGROUND OF THE ART

Memory modules (sometimes referred to as dual inline memory modules or DIMMs) used in computers, servers, and workstations, conventionally include a plurality of memory chips (DRAMs) and other components positioned on a printed circuit board and can include integrated control chips such as registers or advanced memory buffers (AMBs). Historically, operating characteristics have been such that the printed circuit board on which the components are mounted provided sufficient thermal management for the DIMMs. Certain of these chips may operate at higher power than others of the chips, resulting in more heat generated by the higher power chips than the others. These higher power chips create “hot spots,” that is, localized higher temperature areas on the module. These hot spots are disadvantageous, since they can have a negative effect on operation of the memory module or adjacent electronic components. Moreover, during operation of the device containing the memory module, which chip(s) are operating at higher power and, therefore, generating more heat and creating a hot spot, can change over time. Accordingly, the location of a hot spot on a memory module can change with time.

Of particular concern is maintaining the temperature of the DRAMs and integrated control chips below the maximum recommended operating temperature to ensure that the DIMM will operate as intended, and reducing chip temperature as low as is practical to maximize overall DIMM reliability. Since power consumption of the integrated control chips (e.g. 0.5-2 W for registers, 5-7 W typical for AMBs) is typically higher than that of the DRAMs (˜0.1 W), thermal management techniques are often focused on dissipating heat from the integrated control chip and minimizing the adverse effects of that dissipated heat on the surrounding DRAMs. However, hot spot mitigation at the DRAMs is also an important consideration since the location and magnitude of the hot spots on the DIMM (at the DRAMs) can change with air flow, DIMM spacing, and memory access sequences.

One specific type of memory module, fully buffered DIMM (FB-DIMM), is a relatively new type of memory technology developed for the increased speed and capacity of recently developed servers. The key difference and improvement of FB-DIMM technology over traditional DIMM technology is that the memory controller and module communicate via serial communication, rather than by parallel communication as characterized by normal DIMM technology. Physically, this results in fewer wire connections which in turn results in increased memory performance. In order to accomplish this, FB-DIMMs include at least one AMB chip, which operates at higher power than the other chips on the module and, thus, generate more heat than the other chips. In addition, the AMB chip generally extends higher from the board than other chips (or, in the parlance, is taller than other chips on the board), resulting in an irregular contour for the FB-DIMM, making placement of conventional, flat thermal management devices impractical.

Other memory modules such as registered DIMMs (RDIMMs), which buffer data and reduce system loading to enable high density, highly reliable memory systems, also present equivalent heat management issues. The same holds true for very low profile DIMMs (VLP DIMMs), designed for blade servers, and small outline DIMMs (SODIMM) designed for notebook computers.

In addition to heat management for memory modules causing difficulties per se, those difficulties are exacerbated when it is desired that certain international standards governing module thickness, etc., be met. Conventional heat spreaders for memory modules cannot effectively dissipate the amount of heat required while being thin enough to meet some such standards. Moreover, some international standards are written to achieve some thermal purpose, such as to give appropriate spacing between DIMMs during operation to result in appropriate airflow. However DIMM pitch can often be problematic since tighter spacing results in reduced airflow; thus, a thinner spreader than conventional enables more airflow for given DIMM spacing.

In U.S. Pat. No. 6,758,263, Krassowski and Chen disclose the incorporation of a high conducting insert into a heat dissipating component such as a graphite heat sink base in order to conduct heat from a heat source through the thickness of the component, and from there in a planar direction through the thickness of the graphite member.

In U.S. patent application Ser. No. 11/267,933, Reis et al. disclose a graphite-based heat spreader having thermal via extending therethrough. The thermal vias assist in facilitating heat transfer from a heat source into the graphite heat spreader.

Reis, Smalc, Laser, Kostyak, Skandakumaran, Getz and Frastaci disclose a anisotropic graphite heat spreader having a thermal via inserted thereinto, in order to facilitate thermal transfer from a hot spot, especially on a printed circuit board, in U.S. patent application having Ser. No. 11/339,338, entitled “Heat Spreaders With Vias,” filed Jan. 25, 2006, the disclosure of which is incorporated herein by reference.

Graphites are made up of layer planes of hexagonal arrays or networks of carbon atoms. These layer planes of hexagonally arranged carbon atoms are substantially flat and are oriented or ordered so as to be substantially parallel and equidistant to one another. The substantially flat, parallel equidistant sheets or layers of carbon atoms, usually referred to as graphene layers or basal planes, are linked or bonded together and groups thereof are arranged in crystallites. Highly ordered graphites consist of crystallites of considerable size, the crystallites being highly aligned or oriented with respect to each other and having well ordered carbon layers. In other words, highly ordered graphites have a high degree of preferred crystallite orientation. It should be noted that graphites possess anisotropic structures and thus exhibit or possess many properties that are highly directional such as thermal and electrical conductivity.

Briefly, graphites may be characterized as laminated structures of carbon, that is, structures consisting of superposed layers or laminae of carbon atoms joined together by weak van der Waals forces. In considering the graphite structure, two axes or directions are usually noted, to wit, the “c” axis or direction and the “a” axes or directions. For simplicity, the “c” axis or direction may be considered as the direction perpendicular to the carbon layers. The “a” axes or directions may be considered as the directions parallel to the carbon layers or the directions perpendicular to the “c” direction. The graphites suitable for manufacturing flexible graphite sheets possess a very high degree of orientation.

As noted above, the bonding forces holding the parallel layers of carbon atoms together are only weak van der Waals forces. Natural graphites can be treated so that the spacing between the superposed carbon layers or laminae can be appreciably opened up so as to provide a marked expansion in the direction perpendicular to the layers, that is, in the “c” direction, and thus form an expanded or intumesced graphite structure in which the laminar character of the carbon layers is substantially retained.

Graphite flake which has been greatly expanded and more particularly expanded so as to have a final thickness or “c” direction dimension which is as much as about 80 or more times the original “c” direction dimension can be formed without the use of a binder into cohesive or integrated sheets of expanded graphite, e.g. webs, papers, strips, tapes, foils, mats or the like (typically referred to as “flexible graphite”). The formation of graphite particles which have been expanded to have a final thickness or “c” dimension which is as much as about 80 times or more the original “c” direction dimension into integrated flexible sheets by compression, without the use of any binding material, is believed to be possible due to the mechanical interlocking, or cohesion, which is achieved between the voluminously expanded graphite particles.

In addition to flexibility, the sheet material, as noted above, has also been found to possess a high degree of anisotropy with respect to thermal conductivity due to orientation of the expanded graphite particles and graphite layers substantially parallel to the opposed faces of the sheet resulting from high compression, making it especially useful in heat spreading applications. Sheet material thus produced has excellent flexibility, good strength and a high degree of orientation.

Briefly, the process of producing flexible, binderless anisotropic graphite sheet material, e.g. web, paper, strip, tape, foil, mat, or the like, comprises compressing or compacting under a predetermined load and in the absence of a binder, expanded graphite particles which have a “c” direction dimension which is as much as about 80 or more times that of the original particles so as to form a substantially flat, flexible, integrated graphite sheet. The expanded graphite particles that generally are worm-like or vermiform in appearance, once compressed, will maintain the compression set and alignment with the opposed major surfaces of the sheet. The density and thickness of the sheet material can be varied by controlling the degree of compression. The density of the sheet material can be within the range of from about 0.04 g/cc to about 2.0 g/cc.

The flexible graphite sheet material exhibits an appreciable degree of anisotropy due to the alignment of graphite particles parallel to the major opposed, parallel surfaces of the sheet, with the degree of anisotropy increasing upon compression of the sheet material to increase orientation. In compressed anisotropic sheet material, the thickness, i.e. the direction perpendicular to the opposed, parallel sheet surfaces comprises the “c” direction and the directions ranging along the length and width, i.e. along or parallel to the opposed, major surfaces comprises the “a” directions and the thermal and electrical properties of the sheet are very different, by orders of magnitude, for the “c” and “a” directions.

What is desired, therefore, is a thermal management article or device, for reducing hot spots on a memory module caused by one or more of the chips operating at a higher power (and, thus, higher temperature, than other chips), even where the location of the hot spot changes over time. Advantageously, the desired thermal management device should be able to assume a non-planar contour to provide for the situation where one or more of the chips is larger (i.e., taller) than others, such as is the case with the AMB of a FB-DIMM module, and be thin enough to meet industry/application requirements for providing sufficient airflow between DIMMs.

### SUMMARY OF THE INVENTION

Accordingly, it is an object of the invention to provide a construction for improved thermal management of a memory module.

Another object of the present invention is the provision of a graphite-based heat spreader for use with a memory module, where one or more of the memory module components operates at a higher temperature than others.

Still another object of the present invention is providing for improved thermal management of an FB-DIMM memory module.

Yet another object of the invention is to provide a graphite-based heat spreader having a via therein to improve thermal transfer into the spreader.

These objects, as well as others which will be apparent to the skilled artisan upon reading this disclosure, can be attained by providing a memory module comprising a memory board, such as a fully buffered memory board, comprising two major surfaces, at least one of the major surfaces having a plurality of chips thereon, wherein at least one of the chips operates at a higher power than at least one other of the chips, such as an advanced memory buffer chip; and a thermal management system in thermal contact with one or more of the chips which operate at a higher power than at least one other of the chips, wherein the thermal management system spreads heat generated by the one or more of the chips which operate at a higher power than at least one other of the chips with which the thermal management system is in contact. The thermal management system preferably assumes a profile which permits it to remain in thermal contact with a plurality of the chips on the memory board.

The thermal management system advantageously comprises a heat spreader structure which comprises one or more sheets of compressed particles of exfoliated graphite having a thermal pathway therein, wherein the thermal pathway is in thermal contact with at least one of the chips which operates at a higher power than at least one other of the chips to facilitate heat transfer from such chip into the heat spreader structure. The thermal pathway should extend through the heat spreader structure and comprises a material having a thermal conductivity in the direction between the at least one of the chips which operates at a higher power than at least one other of the chips and the heat spreader structure greater than the through-thickness thermal conductivity of the heat spreader structure. More particularly, the thermal pathway should have a thermal conductivity of at least about 100 W/mK, more preferably at least about 200 W/mK.

In addition, the inventive memory module can further comprise a heat spreader in thermal contact with the major surface of the memory board other than the surface on which are the chips. Also a rigidifying material can maintain the profile of the thermal management system, and a thermal interface material can be positioned between the thermal management system and the memory board.

Other and further objects, features, and advantages of the present invention will be readily apparent to those skilled in the art, upon a reading of the following disclosure when taken in conjunction with the accompanying drawings.

### BRIEF DESCRIPTION OF THE DRAWINGS

FIG. 1A is a side perspective view of one embodiment of a memory module in accordance with the present invention.

FIG. 1B is a top plan view of the memory module of FIG. 1A.

FIG. 1C is a side plan view of the memory module of FIG. 1A.

FIG. 2 is a side plan view of another embodiment of a memory module in accordance with the present invention.

FIG. 3 is a partial cross-section view of the thermal management system in accordance with the present invention, illustrating the thermal pathway.

### DETAILED DESCRIPTION OF THE INVENTION

Graphite is a crystalline form of carbon comprising atoms covalently bonded in flat layered planes with weaker bonds between the planes. By treating particles of graphite, such as natural graphite flake, with an intercalant of, e.g. a solution of sulfuric and nitric acid, the crystal structure of the graphite reacts to form a compound of graphite and the intercalant. The treated particles of graphite are hereafter referred to as “particles of intercalated graphite.” Upon exposure to high temperature, the intercalant within the graphite decomposes and volatilizes, causing the particles of intercalated graphite to expand in dimension as much as about 80 or more times its original volume in an accordion-like fashion in the “c” direction, i.e. in the direction perpendicular to the crystalline planes of the graphite. The exfoliated graphite particles are vermiform in appearance, and are therefore commonly referred to as worms. The worms may be compressed together into flexible sheets that, unlike the original graphite flakes, can be formed and cut into various shapes.

Graphite starting materials suitable for use in the present invention include highly graphitic carbonaceous materials capable of intercalating organic and inorganic acids as well as halogens and then expanding when exposed to heat. These highly graphitic carbonaceous materials most preferably have a degree of graphitization of about 1.0. As used in this disclosure, the term “degree of graphitization” refers to the value g according to the formula:

$$g = \frac{3.45 - d ( 002 )}{0.095}$$

where d(002) is the spacing between the graphitic layers of the carbons in the crystal structure measured in Angstrom units. The spacing d between graphite layers is measured by standard X-ray diffraction techniques. The positions of diffraction peaks corresponding to the (002), (004) and (006) Miller Indices are measured, and standard least-squares techniques are employed to derive spacing which minimizes the total error for all of these peaks. Examples of highly graphitic carbonaceous materials include natural graphites from various sources, as well as other carbonaceous materials such as graphite prepared by chemical vapor deposition, high temperature pyrolysis of polymers, or crystallization from molten metal solutions and the like. Natural graphite is most preferred.

The graphite starting materials used in the present invention may contain non-graphite components so long as the crystal structure of the starting materials maintains the required degree of graphitization and they are capable of exfoliation. Generally, any carbon-containing material, the crystal structure of which possesses the required degree of graphitization and which can be exfoliated, is suitable for use with the present invention. Such graphite preferably has a purity of at least about eighty weight percent. More preferably, the graphite employed for the present invention will have a purity of at least about 94%. In the most preferred embodiment, the graphite employed will have a purity of at least about 98%.

A common method for manufacturing graphite sheet is described by Shane et al. in U.S. Pat. No. 3,404,061, the disclosure of which is incorporated herein by reference. In the typical practice of the Shane et al. method, natural graphite flakes are intercalated by dispersing the flakes in a solution containing e.g., a mixture of nitric and sulfuric acid, advantageously at a level of about 20 to about 300 parts by weight of intercalant solution per 100 parts by weight of graphite flakes (pph). The intercalation solution contains oxidizing and other intercalating agents known in the art. Examples include those containing oxidizing agents and oxidizing mixtures, such as solutions containing nitric acid, potassium chlorate, chromic acid, potassium permanganate, potassium chromate, potassium dichromate, perchloric acid, and the like, or mixtures, such as for example, concentrated nitric acid and chlorate, chromic acid and phosphoric acid, sulfuric acid and nitric acid, or mixtures of a strong organic acid, e.g. trifluoroacetic acid, and a strong oxidizing agent soluble in the organic acid. Alternatively, an electric potential can be used to bring about oxidation of the graphite. Chemical species that can be introduced into the graphite crystal using electrolytic oxidation include sulfuric acid as well as other acids.

In a preferred embodiment, the intercalating agent is a solution of a mixture of sulfuric acid, or sulfuric acid and phosphoric acid, and an oxidizing agent, i.e. nitric acid, perchloric acid, chromic acid, potassium permanganate, hydrogen peroxide, iodic or periodic acids, or the like. Although less preferred, the intercalation solution may contain metal halides such as ferric chloride, and ferric chloride mixed with sulfuric acid, or a halide, such as bromine as a solution of bromine and sulfuric acid or bromine in an organic solvent.

The quantity of intercalation solution may range from about 20 to about 350 pph and more typically about 40 to about 160 pph. After the flakes are intercalated, any excess solution is drained from the flakes and the flakes are water-washed. Alternatively, the quantity of the intercalation solution may be limited to between about 10 and about 40 pph, which permits the washing step to be eliminated as taught and described in U.S. Pat. No. 4,895,713, the disclosure of which is also herein incorporated by reference.

The particles of graphite flake treated with intercalation solution can optionally be contacted, e.g. by blending, with a reducing organic agent selected from alcohols, sugars, aldehydes and esters which are reactive with the surface film of oxidizing intercalating solution at temperatures in the range of 25° C. and 125° C. Suitable specific organic agents include hexadecanol, octadecanol, 1-octanol, 2-octanol, decylalcohol, 1,10 decanediol, decylaldehyde, 1-propanol, 1,3 propanediol, ethyleneglycol, polypropylene glycol, dextrose, fructose, lactose, sucrose, potato starch, ethylene glycol monostearate, diethylene glycol dibenzoate, propylene glycol monostearate, glycerol monostearate, dimethyl oxylate, diethyl oxylate, methyl formate, ethyl formate, ascorbic acid and lignin-derived compounds, such as sodium lignosulfate. The amount of organic reducing agent is suitably from about 0.5 to 4% by weight of the particles of graphite flake.

The use of an expansion aid applied prior to, during or immediately after intercalation can also provide improvements. Among these improvements can be reduced exfoliation temperature and increased expanded volume (also referred to as “worm volume”). An expansion aid in this context will advantageously be an organic material sufficiently soluble in the intercalation solution to achieve an improvement in expansion. More narrowly, organic materials of this type that contain carbon, hydrogen and oxygen, preferably exclusively, may be employed. Carboxylic acids have been found especially effective. A suitable carboxylic acid useful as the expansion aid can be selected from aromatic, aliphatic or cycloaliphatic, straight chain or branched chain, saturated and unsaturated monocarboxylic acids, dicarboxylic acids and polycarboxylic acids which have at least 1 carbon atom, and preferably up to about 15 carbon atoms, which is soluble in the intercalation solution in amounts effective to provide a measurable improvement of one or more aspects of exfoliation. Suitable organic solvents can be employed to improve solubility of an organic expansion aid in the intercalation solution.

Representative examples of saturated aliphatic carboxylic acids are acids such as those of the formula H(CH₂)ₙCOOH wherein n is a number of from 0 to about 5, including formic, acetic, propionic, butyric, pentanoic, hexanoic, and the like. In place of the carboxylic acids, the anhydrides or reactive carboxylic acid derivatives such as alkyl esters can also be employed. Representative of alkyl esters are methyl formate and ethyl formate. Sulfuric acid, nitric acid and other known aqueous intercalants have the ability to decompose formic acid, ultimately to water and carbon dioxide. Because of this, formic acid and other sensitive expansion aids are advantageously contacted with the graphite flake prior to immersion of the flake in aqueous intercalant. Representative of dicarboxylic acids are aliphatic dicarboxylic acids having 2-12 carbon atoms, in particular oxalic acid, fumaric acid, malonic acid, maleic acid, succinic acid, glutaric acid, adipic acid, 1,5-pentanedicarboxylic acid, 1,6-hexanedicarboxylic acid, 1,10-decanedicarboxylic acid, cyclohexane-1,4-dicarboxylic acid and aromatic dicarboxylic acids such as phthalic acid or terephthalic acid. Representative of alkyl esters are dimethyl oxylate and diethyl oxylate. Representative of cycloaliphatic acids is cyclohexane carboxylic acid and of aromatic carboxylic acids are benzoic acid, naphthoic acid, anthranilic acid, p-aminobenzoic acid, salicylic acid, o-, m- and p-tolyl acids, methoxy and ethoxybenzoic acids, acetoacetamidobenzoic acids and, acetamidobenzoic acids, phenylacetic acid and naphthoic acids. Representative of hydroxy aromatic acids are hydroxybenzoic acid, 3-hydroxy-1-naphthoic acid, 3-hydroxy-2-naphthoic acid, 4-hydroxy-2-naphthoic acid, 5-hydroxy-1-naphthoic acid, 5-hydroxy-2-naphthoic acid, 6-hydroxy-2-naphthoic acid and 7-hydroxy-2-naphthoic acid. Prominent among the polycarboxylic acids is citric acid.

The intercalation solution will be aqueous and will preferably contain an amount of expansion aid of from about 1 to 10%, the amount being effective to enhance exfoliation. In the embodiment wherein the expansion aid is contacted with the graphite flake prior to or after immersing in the aqueous intercalation solution, the expansion aid can be admixed with the graphite by suitable means, such as a V-blender, typically in an amount of from about 0.2% to about 10% by weight of the graphite flake.

After intercalating the graphite flake, and following the blending of the intercalant coated intercalated graphite flake with the organic reducing agent, the blend is exposed to temperatures in the range of 25° to 125° C. to promote reaction of the reducing agent and intercalant coating. The heating period is up to about 20 hours, with shorter heating periods, e.g., at least about 10 minutes, for higher temperatures in the above-noted range. Times of one half hour or less, e.g., on the order of 10 to 25 minutes, can be employed at the higher temperatures.

The thusly treated particles of graphite are sometimes referred to as “particles of intercalated graphite.” Upon exposure to high temperature, e.g. temperatures of at least about 160° C. and especially about 700° C. to 1000° C. and higher, the particles of intercalated graphite expand as much as about 80 to 1000 or more times their original volume in an accordion-like fashion in the c-direction, i.e. in the direction perpendicular to the crystalline planes of the constituent graphite particles. The expanded, i.e. exfoliated, graphite particles are vermiform in appearance, and are therefore commonly referred to as worms. The worms may be compressed together into flexible sheets that, unlike the original graphite flakes, can be formed and cut into various shapes.

Flexible graphite sheet and foil are coherent, with good handling strength, and are suitably compressed, e.g. by roll pressing, to a thickness of about 0.075 mm to 3.75 mm and a typical density of about 0.1 to 1.9 grams per cubic centimeter (g/cm³). From about 1.5-30% by weight of ceramic additives can be blended with the intercalated graphite flakes as described in U.S. Pat. No. 5,902,762 (which is incorporated herein by reference) to provide enhanced resin impregnation in the final flexible graphite product. The additives include ceramic fiber particles having a length of about 0.15 to 1.5 millimeters. The width of the particles is suitably from about 0.04 to 0.004 mm. The ceramic fiber particles are non-reactive and non-adhering to graphite and are stable at temperatures up to about 1100° C., preferably about 1400° C. or higher. Suitable ceramic fiber particles are formed of macerated quartz glass fibers, carbon and graphite fibers, zirconia, boron nitride, silicon carbide and magnesia fibers, naturally occurring mineral fibers such as calcium metasilicate fibers, calcium aluminum silicate fibers, aluminum oxide fibers and the like.

The above described methods for intercalating and exfoliating graphite flake may beneficially be augmented by a pretreatment of the graphite flake at graphitization temperatures, i.e. temperatures in the range of about 3000° C. and above and by the inclusion in the intercalant of a lubricious additive, as described in International Patent Application No. PCT/US02/39749, the disclosure of which is incorporated herein by reference.

The pretreatment, or annealing, of the graphite flake results in significantly increased expansion (i.e., increase in expansion volume of up to 300% or greater) when the flake is subsequently subjected to intercalation and exfoliation. Indeed, desirably, the increase in expansion is at least about 50%, as compared to similar processing without the annealing step. The temperatures employed for the annealing step should not be significantly below 3000° C., because temperatures even 100° C. lower result in substantially reduced expansion.

The annealing of the present invention is performed for a period of time sufficient to result in a flake having an enhanced degree of expansion upon intercalation and subsequent exfoliation. Typically the time required will be 1 hour or more, preferably 1 to 3 hours and will most advantageously proceed in an inert environment. For maximum beneficial results, the annealed graphite flake will also be subjected to other processes known in the art to enhance the degree expansion—namely intercalation in the presence of an organic reducing agent, an intercalation aid such as an organic acid, and a surfactant wash following intercalation. Moreover, for maximum beneficial results, the intercalation step may be repeated.

The annealing step of the instant invention may be performed in an induction furnace or other such apparatus as is known and appreciated in the art of graphitization; for the temperatures here employed, which are in the range of 3000° C., are at the high end of the range encountered in graphitization processes.

Because it has been observed that the worms produced using graphite subjected to pre-intercalation annealing can sometimes “clump” together, which can negatively impact area weight uniformity, an additive that assists in the formation of “free flowing” worms is highly desirable. The addition of a lubricious additive to the intercalation solution facilitates the more uniform distribution of the worms across the bed of a compression apparatus (such as the bed of a calender station) conventionally used for compressing (or “calendering”) graphite worms into flexible graphite sheet. The resulting sheet therefore has higher area weight uniformity and greater tensile strength. The lubricious additive is preferably a long chain hydrocarbon, more preferably a hydrocarbon having at least about 10 carbons. Other organic compounds having long chain hydrocarbon groups, even if other functional groups are present, can also be employed.

More preferably, the lubricious additive is an oil, with a mineral oil being most preferred, especially considering the fact that mineral oils are less prone to rancidity and odors, which can be an important consideration for long term storage. It will be noted that certain of the expansion aids detailed above also meet the definition of a lubricious additive. When these materials are used as the expansion aid, it may not be necessary to include a separate lubricious additive in the intercalant.

The lubricious additive is present in the intercalant in an amount of at least about 1.4 pph, more preferably at least about 1.8 pph. Although the upper limit of the inclusion of lubricous additive is not as critical as the lower limit, there does not appear to be any significant additional advantage to including the lubricious additive at a level of greater than about 4 pph.

The flexible graphite sheets of the present invention may, if desired, utilize particles of reground flexible graphite sheets rather than freshly expanded worms, as discussed in U.S. Pat. No. 6,673,289 to Reynolds, Norley and Greinke, the disclosure of which is incorporated herein by reference. The sheets may be newly formed sheet material, recycled sheet material, scrap sheet material, or any other suitable source.

Also the processes of the present invention may use a blend of virgin materials and recycled materials.

The source material for recycled materials may be sheets or trimmed portions of sheets that have been compression molded as described above, or sheets that have been compressed with, for example, pre-calendering rolls, but have not yet been impregnated with resin. Furthermore, the source material may be sheets or trimmed portions of sheets that have been impregnated with resin, but not yet cured, or sheets or trimmed portions of sheets that have been impregnated with resin and cured. The source material may also be recycled flexible graphite proton exchange membrane (PEM) fuel cell components such as flow field plates or electrodes. Each of the various sources of graphite may be used as is or blended with natural graphite flakes.

Once the source material of flexible graphite sheets is available, it can then be comminuted by known processes or devices, such as a jet mill, air mill, blender, etc. to produce particles. Preferably, a majority of the particles have a diameter such that they will pass through 20 U.S. mesh; more preferably a major portion (greater than about 20%, most preferably greater than about 50%) will not pass through 80 U.S. mesh. Most preferably the particles have a particle size of no greater than about 20 U.S. mesh. It may be desirable to cool the flexible graphite sheet when it is resin-impregnated as it is being comminuted to avoid heat damage to the resin system during the comminution process.

The size of the comminuted particles may be chosen so as to balance machinability and formability of the graphite article with the thermal characteristics desired. Thus, smaller particles will result in a graphite article which is easier to machine and/or form, whereas larger particles will result in a graphite article having higher anisotropy, and, therefore, greater in-plane electrical and thermal conductivity.

Once the source material is comminuted, it is then re-expanded. The re-expansion may occur by using the intercalation and exfoliation process described above and those described in U.S. Pat. No. 3,404,061 to Shane et al. and U.S. Pat. No. 4,895,713 to Greinke et al.

Typically, after intercalation the particles are exfoliated by heating the intercalated particles in a furnace. During this exfoliation step, intercalated natural graphite flakes may be added to the recycled intercalated particles. Preferably, during the re-expansion step the particles are expanded to have a specific volume in the range of at least about 100 cc/g and up to about 350 cc/g or greater. Finally, after the re-expansion step, the re-expanded particles may be compressed into flexible sheets, as hereinafter described.

According to the invention, graphite sheets prepared as described above (which typically have a thickness of about 0.075 mm to about 10 mm, but which can vary depending, e.g., on the degree of compression employed) are can be treated with resin and the absorbed resin, after curing, enhances the moisture resistance and handling strength, i.e. stiffness, of the sheet as well as “fixing” the morphology of the sheet. The amount of resin within the epoxy impregnated graphite sheets should be an amount sufficient to ensure that the final assembled and cured layered structure is dense and cohesive, yet the anisotropic thermal conductivity associated with a densified graphite structure has not been adversely impacted. Suitable resin content is preferably at least about 5% by weight, more preferably about 10 to 35% by weight, and suitably up to about 60% by weight.

Resins found especially useful in the practice of the present invention include acrylic-, epoxy- and phenolic-based resin systems, fluoro-based polymers, or mixtures thereof. Suitable epoxy resin systems include those based on diglycidyl ether of bisphenol A (DGEBA) and other multifunctional resin systems; phenolic resins that can be employed include resole and novolac phenolics. Optionally, the flexible graphite may be impregnated with fibers and/or salts in addition to the resin or in place of the resin. Additionally, reactive or non-reactive additives may be employed with the resin system to modify properties (such as tack, material flow, hydrophobicity, etc.).

One type of apparatus for continuously forming resin-impregnated and compressed flexible graphite materials is shown in U.S. Pat. No. 6,706,400 to Mercuri, Capp, Warddrip and Weber, the disclosure of which is incorporated herein by reference.

Advantageously, when the sheets of compressed particles of exfoliated graphite are resin-impregnated, following the compression step (such as by calendering), the impregnated materials are cut to suitable-sized pieces and placed in a press, where the resin is cured at an elevated temperature. In addition, the flexible graphite sheets can be employed in the form of a laminate, which can be prepared by stacking together individual graphite sheets in the press.

The temperature employed in the press should be sufficient to ensure that the graphite structure is densified at the curing pressure, while the thermal properties of the structure are not adversely impacted. Generally, this will require a temperature of at least about 90° C., and generally up to about 200° C. Most preferably, cure is at a temperature of from about 150° C. to 200° C. The pressure employed for curing will be somewhat a function of the temperature utilized, but will be sufficient to ensure that the graphite structure is densified without adversely impacting the thermal properties of the structure. Generally, for convenience of manufacture, the minimum required pressure to densify the structure to the required degree will be utilized. Such a pressure will generally be at least about 7 megapascals (Mpa, equivalent to about 1000 pounds per square inch), and need not be more than about 35 Mpa (equivalent to about 5000 psi), and more commonly from about 7 to about 21 Mpa (1000 to 3000 psi). The curing time may vary depending on the resin system and the temperature and pressure employed, but generally will range from about 0.5 hours to 2 hours. After curing is complete, the materials are seen to have a density of at least about 1.8 g/cm³ and commonly from about 1.8 g/cm³ to 2.0 g/cm³.

Advantageously, when the flexible graphite sheets are themselves presented as a laminate, the resin present in the impregnated sheets can act as the adhesive for the laminate. According to another embodiment of the invention, however, the calendered, impregnated, flexible graphite sheets are coated with an adhesive before the flexible sheets are stacked and cured. Suitable adhesives include epoxy-, acrlylic- and phenolic-based resins. Phenolic resins found especially useful in the practice of the present invention include phenolic-based resin systems including resole and novolak phenolics.

Although the formation of sheets through calendering or molding is the most common method of formation of the graphite materials useful in the practice of the present invention, other forming methods can also be employed.

The temperature- and pressure-cured graphite/resin composites of the present invention provide a graphite-based composite material having in-plane thermal conductivity rivaling or exceeding that of copper, at a fraction of the weight of copper. More specifically, the composites exhibit in-plane thermal conductivities of at least about 300 W/mK, with through-plane thermal conductivities of less than about 15 W/mK, more preferably less than about 10 W/mK.

The present invention provides a heat spreader for use with a memory module, especially an FB-DIMM, which includes a sheet of compressed particles of exfoliated graphite having at least one flanged thermal via which engages a heat source on the memory module and spread the heat therefrom. Such a flanged via may be secured to the graphite heat spreader either through the use of a push-on nut or the use of a second flange which is rigidly connected to the stem of the via. Thus such flanged vias include at least one flange, and either a second flange or a push on nut all of which extend above the surface of the graphite heat spreader sheet. In another embodiment, flush thermal vias are provided which in the final position are flush with the major planar surfaces of the graphite heat spreader. Both embodiments preferably involve the method of manufacture wherein the stem of the via is force fit into a similarly shaped but slightly smaller opening through the graphite planar element to provide a close fit between the stem and the opening through the graphite planar element. Alternatively, the via itself can punch the hole in the graphite heat spreader as it is being inserted thereinto.

As noted above, a memory module can contain one or more chips operating at higher power (and, thus, generating more heat) than others; in the case of an FB-DIMM, these chips are referred to as advanced memory buffer chips (AMBs), which act as sort of a “traffic cop” for the other chips. The AMB maximizes speed and bandwidth compared to traditional memory modules by directing the storage and retrieval of information to and from the memory chips directly on the memory module. While most FB-DIMMs have one AMB, the use of more than one has been contemplated. The higher power chips on memory modules create “hot spots” in the surface of the memory module, which can deleteriously affect adjacent chips or components. For the purposes of this application, these higher power chips are referred to as “hot spot sources.”

The use of one or more sheets of compressed particles of exfoliated graphite can spread the heat from these hot spot sources, to thus eliminate hot spots on the memory module and cool the heat source. While dissipation of the heat may not be significant, the use of a graphite heat spreader in the manner of the present invention ensures that the temperature across the memory module is relatively uniform, reducing those locations experiencing significantly higher temperatures. In order to facilitate heat transfer into the body of the anisotropic graphite material, where thermal conductivities are significantly higher in the plane of the sheet (as high as about 300 W/mK, or even as high as about 400 W/mK or higher, potentially as high as about about 600 W/mK) than through the plane of the sheet (as low as about 10 W/mK, or even as low as 5 W/mK or lower, even as low as about 2 W/mK), by a factor of 10:1 or even 20:1 or higher, a thermal via is inserted through the graphite structure to pull heat through the thickness of the sheet to permit it to spread across the plane of the spreader.

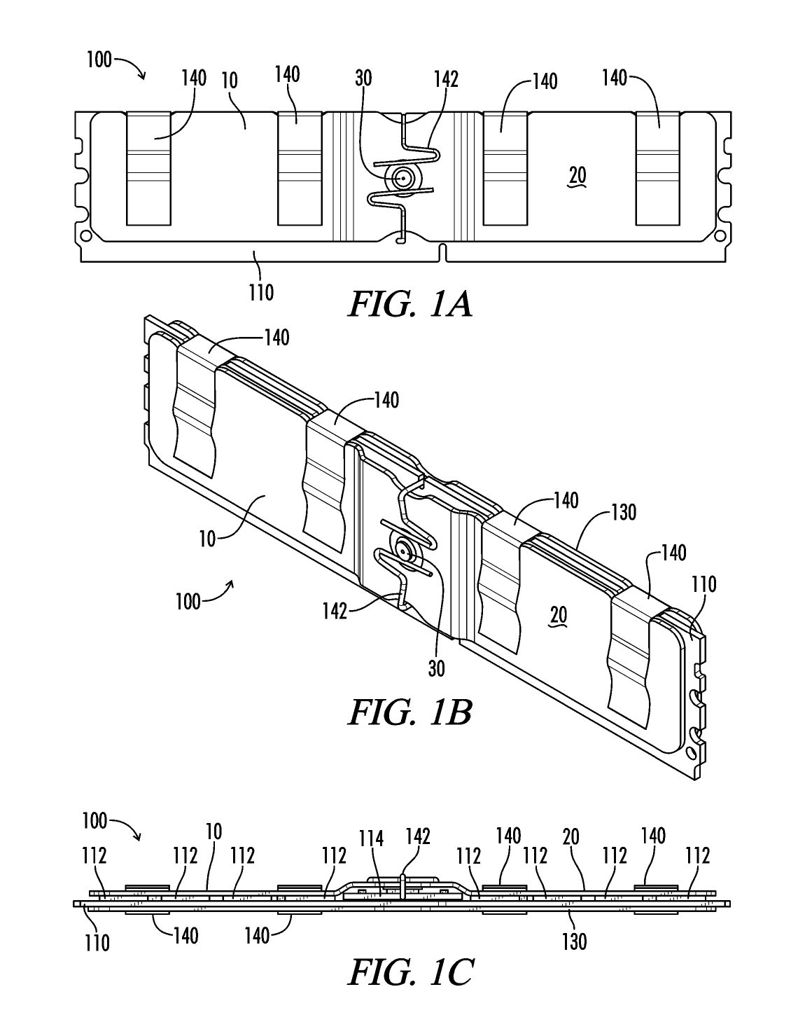

Referring now to the drawings, FIGS. 1A-1C illustrate a memory module 100, such as an FB-DIMM, having a graphite-based thermal management system 10. Memory module 100 includes a memory board 110 having memory chips 112 thereon. At least one (and, optionally more than one) of memory chips 112 operates at a higher power than others of memory chips 112, and is designated 114. For instance, where memory module 100 is an FB-DIMM, higher power chip 114 can be one or more AMBs. Memory module 100 can also comprise a relatively flat heat spreader 130 on the surface opposite the surface having chips 112 thereon (colloquially referred to as the “bottom” of memory module 100). Spreader 130 functions to provide further heat spreading, and can comprise one or more sheets of compressed particles of exfoliated graphite.

In addition, the entire memory module 100 structure, including memory board 110, thermal management system 10, and heat spreader 130 (when employed) can optionally be held together by one or more clips 140 and retaining member 142, typically formed of a metal like steel or aluminum, and which keep the elements of memory module 100 in thermal contact with each other by maintaining the entire unit under pressure. Indeed, retaining member 142 can also function as a registration means, aligning with notches in memory board 110 to ensure proper alignment of the different elements of memory module 100, as shown in FIGS. 1A and 1B. Other registration features (not shown) can also be employed. For instance, thermal management system 10 can feature a tab which folds into a corresponding notch in memory board 110 and/or heat spreader 130 to ensure proper alignment; alternatively, heat spreader 130 can have the tab, which folds into a notch in memory board 110 and/or thermal management system 10.

In the preferred embodiment, thermal management system 10 comprises a heat spreader structure 20 which comprises one or more sheets of compressed particles of exfoliated graphite having a thermal pathway 30 therein to facilitate heat transfer from higher power chip(s) 114 into heat spreader structure 20. Because chips 112 on the surface of memory module 100 are not of uniform height, or distance from the surface of memory board 110, a flat heat spreader such as an aluminum heat spreader conventional in the art, will not be effective, since it will not make good thermal contact across the surface of memory module 100. More specifically, higher power chip(s) 114 can extend higher from the surface of memory board 110. Thus, thermal management system 10 often must be capable of being formed into a complex, or three-dimensional shape or profile, to match the profile of memory module 100 having chips 112 and 114 of differing heights, and which allows thermal management system to remain in thermal contact with chips 112 and 114. By “thermal contact” is meant sufficient contact or relative position to permit thermal transfer.

As discussed, in order to facilitate the transfer of heat from a higher power chip 114 to a graphite heat spreader layer 20, a thermal pathway 30, also referred to as a thermal via or rivet or simply a via 30, extends through graphite heat spreader layer 20, adjacent higher power chip 114. In the event memory module 100 has more than one higher power chip 114, more than one thermal pathway 30 can be employed. Via 30 comprises a slug or “rivet” of a high thermal conductivity material, such as copper or alloys thereof, although other high thermal conductivity materials like aluminum or compressed particles of exfoliated graphite can be used. By “high thermal conductivity” is meant that the thermal conductivity of via 30 in the direction between higher power chip 114 and heat spreader layer 20 is greater than the through-thickness thermal conductivity of heat spreader layer 20 (in other words, the thermal conductivity of via 30 in the direction corresponding to the through-thickness direction of heat spreader layer 20 is greater than the through-thickness thermal conductivity of heat spreader layer 20); preferably, the thermal conductivity of via 30 is at least about 100 W/mK, more preferably at least about 200 W/mK, and even more preferably above 350 W/mK. Each via 30 can assume any particular cross-sectional shape, although most commonly, via 30 will be cylindrical in shape.

Referring now to FIG. 3, via 30 may comprise a via which is inserted within graphite heat spreader layer 20. Such a via 30 has a flange 32 which is rigidly connected to via 30 and which sits against the surface of layer 20, and may be attached to the graphite heat spreader 20 either through the use of a push on nut 31, or the use of a second flange (not shown). Thus such vias 30 include at least one flange, and either a second flange or a push on nut all of which extend above the surface of the graphite heat spreader element. In another embodiment, flush thermal vias are provided which in the final position are flush with the major planar surfaces of the graphite heat spreader element. Various preferred techniques for manufacturing both embodiments are provided. Both embodiments preferably involve the method of manufacture wherein the stem of the via is force fit into a similarly shaped but slightly smaller opening through the graphite planar element to provide a close fit between the stem and the opening through the graphite planar element, although the via can be used itself to punch the hole through the graphite planar element.

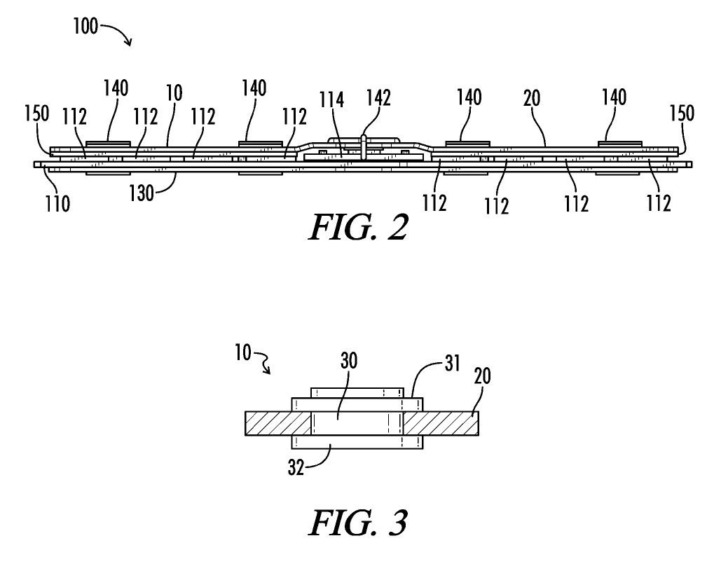

In addition, where desirable, a thermal interface material 150 can be positioned between graphite-based thermal management system 10 and chips 112 on memory board 110 in order to facilitate thermal transfer between chips 112 and thermal management system 10, as illustrated in FIG. 2. Additionally, thermal interface material 150 can also be positioned between graphite-based thermal management system 10 and chip 114, also to facilitate thermal transfer. Thermal interface material can comprise any conventional thermal interface material, such as a phase change material. Additionally, when positioned between thermal management system 10 and chips 112, thermal interface material 150 can be a dielectric material such as polyethyelene terephthalate (PET).

Moreover, a rigidifying material, such as a stamped aluminum plate (not shown) can be used to assist in maintaining graphite thermal management system 10 in the desired contour; in addition, a rigidifying material, when formed of an isotropic, relatively thermally conductive material like a metal such as aluminum or copper, can facilitate thermal management. In addition, the rigidifying material can be provided with surface roughness or structures such as dimples, fingers or the like, which can act to increase airflow turbulence about the surface of the rigidifying material and thus improve thermal dissipation.

Thus, the present invention can provide effective thermal management for a memory module, such as an FB-DIMM, having one or more higher power chips, while maintaining compliance with international standards.

All cited patents, patent applications and publications referred to in this application are incorporated by reference.

The above description is intended to enable the person skilled in the art to practice the invention. It is not intended to detail all of the possible variations and modifications that will become apparent to the skilled worker upon reading the description. It is intended, however, that all such modifications and variations be included within the scope of the invention that is defined by the following claims. The claims are intended to cover the indicated elements and steps in any arrangement or sequence that is effective to meet the objectives intended for the invention, unless the context specifically indicates the contrary.

What is claimed is:

1. A memory module comprising:
a. a memory board comprising two major surfaces, one of the major surfaces having a plurality of chips thereon, wherein at least one of the chips operates at a higher power than at least one other of the chips; and
b. a thermal management system in thermal contact with one or more of the chips which operate at a higher power than at least one other of the chips, wherein the thermal management system spreads heat generated by the one or more of the chips which operate at a higher power than at least one other of the chips with which the thermal management system is in contact, wherein the thermal management system comprises a heat spreader structure which comprises one or more sheets of compressed particles of exfoliated graphite having a thermal pathway therein, wherein the thermal pathway is in thermal contact with at least one of the chips which operates at a higher power than at least one other of the chips to facilitate heat transfer from such chip into the heat spreader structure.

2. The memory module of claim 1, wherein the thermal management system assumes a profile which permits it to remain in thermal contact with a plurality of the chips on the memory board.

3. The memory module of claim 1, wherein the thermal pathway extends through the heat spreader structure.

4. The memory module of claim 3, wherein the thermal pathway comprises a material having a thermal conductivity in the direction corresponding to the through-thickness direction of the heat spreader structure greater than the through-thickness thermal conductivity of the heat spreader structure.

5. The memory module of claim 4, wherein the thermal pathway has a thermal conductivity of at least about 100 W/mK.

6. The memory module of claim 5, wherein the thermal pathway has a thermal conductivity of at least about 200 W/mK.

7. The memory module of claim 1, which further comprises a heat spreader in thermal contact with the major surface of the memory board other than the surface on which are the chips.

8. The memory module of claim 2, which further comprises a rigidifying material which maintains the profile of the thermal management system.

9. The memory module of claim 8, wherein the rigidifying material comprises aluminum.

10. The memory module of claim 8, wherein the rigidifying material has a surface which increase airflow turbulence thereabout.

11. The memory module of claim 2, which further comprises a thermal interface material between the thermal management system and the memory board.

12. A fully buffered memory module comprising:
a. a memory board comprising two major surfaces, one of the major surfaces having a plurality of chips thereon, wherein at least one of the chips comprises an advanced memory buffer chip; and
b. a thermal management system in thermal contact with one or more of the advanced memory buffer chips, wherein the thermal management system spreads heat generated by the one or more of the advanced memory buffer chips, wherein the thermal management system comprises a heat spreader structure which comprises one or more sheets of compressed particles of exfoliated graphite having a thermal pathway therein, wherein the thermal pathway is in thermal contact with at least one of the advanced memory buffer chips to facilitate heat transfer from such chip into the heat spreader structure.

13. The fully buffered memory module of claim 12, wherein the thermal management system assumes a profile which permits it to remain in thermal contact with a plurality of the chips on the memory board.

14. The fully buffered memory module of claim 12, wherein the thermal pathway extends through the heat spreader structure.

15. The fully buffered memory module of claim 14, wherein the thermal pathway comprises a material having a thermal conductivity in the direction corresponding to the through-thickness direction of the heat spreader structure greater than the through-thickness thermal conductivity of the heat spreader structure.

16. The fully buffered memory module of claim 15, wherein the thermal pathway has a thermal conductivity of at least about 100 W/mK.

17. The fully buffered memory module of claim 16, wherein the thermal pathway has a thermal conductivity of at least about 200 W/mK.

18. The fully buffered memory module of claim 12, which further comprises a heat spreader in thermal contact with the major surface of the memory board other than the surface on which are the chips.

19. The fully buffered memory module of claim 12, which further comprises a rigidfying material which maintains the profile of the thermal management system.

20. The fully buffered memory module of claim 19, wherein the rigidifying material comprises aluminum.

21. The fully buffered memory module of claim 19, wherein the rigidifying material has a surface which increase airflow turbulence thereabout.

22. The fully buffered memory module of claim 12, which further comprises a thermal interface material between the thermal management system and the memory board.
